(19) United States
(12) Patent Application Publication
(10) Pub. No.: US 2025/0133729 A1
(43) Pub. Date: Apr. 24, 2025

(54) SEMICONDUCTOR MEMORY DEVICE

(71) Applicant: Samsung Electronics Co., Ltd., Suwon-si (KR)

(72) Inventors: Taejin Park, Suwon-si (KR); Kyusul Park, Suwon-si (KR); Sungsoo Yim, Suwon-si (KR); Taeha Suh, Suwon-si (KR); Hyeonkyu Lee, Suwon-si (KR)

(21) Appl. No.: 18/668,696

(22) Filed: May 20, 2024

(30) Foreign Application Priority Data
Oct. 18, 2023 (KR) 10-2023-0139877

(51) Int. Cl. H10B 12/00

(52) U.S. Cl. CPC H10B 12/485; H10B 12/05; H10B 12/315

(57) ABSTRACT

A semiconductor memory device includes a conductive line extending in a first direction, channel regions spaced apart from each other in the first direction over the conductive line and each electrically connected to the conductive line, a back gate electrode spaced apart from the conductive line in a third direction and extending in a second direction between first and second channel regions selected from the channel regions, a pair of word lines spaced apart from each other in the first direction and between the second and third channel regions selected from the channel regions, and epitaxial direct contact plugs extending in the third direction between the channel regions and the conductive line and each including a contact surface contacting one of the channel regions, a protruding contact portion at least partially surrounded by the conductive line, and a vertical contact portion between the contact surface and the protruding contact portion.

### CROSS-REFERENCE TO RELATED APPLICATION

This application is based on and claims priority under 35 U.S.C. § 119 to Korean Patent Application No. 10-2023-0139877, filed on Oct. 18, 2023, in the Korean Intellectual Property Office, the disclosure of which is incorporated by reference herein in its entirety.

### BACKGROUND

Embodiments of the inventive concept relate to a semiconductor memory device, and more particularly, to a semiconductor memory device including a vertical channel transistor.

Along with the rapid down-scaling of integrated circuit devices, semiconductor memory devices may be required to provide high operation speeds and improved accuracy in operations as well. Therefore, research has been conducted to provide semiconductor memory devices that have structures capable of improving the performance and the reliability thereof.

### SUMMARY

Embodiments of the inventive concept provide a semiconductor memory device that is configured to mitigate or prevent thermal damage to unit devices through a contact structure, which may be formed by a low-temperature process during the fabrication process of the semiconductor memory device including a vertical channel transistor, the semiconductor memory device having a structure exhibiting improved electrical characteristics due to the contact structure providing a relatively large contact area.

According to an aspect of the inventive concept, there is provided a semiconductor memory device including a conductive line extending lengthwise in a first direction, a plurality of channel regions arranged over the conductive line and spaced apart from each other in the first direction, each of the plurality of channel regions being configured to be electrically connected to the conductive line, a back gate electrode spaced apart from the conductive line in a third direction and extending in a second direction between a first channel region and a second channel region, which are selected from the plurality of channel regions and are adjacent to each other, the first, second, and third directions being perpendicular with respect to each other, a pair of word lines spaced apart from each other in the first direction and arranged between the second channel region and a third channel region, which are selected from the plurality of channel regions and are adjacent to each other, and a plurality of epitaxial direct contact plugs extending in the third direction between the plurality of channel regions and the conductive line, each of the plurality of epitaxial direct contact plugs including a contact surface contacting one of the plurality of channel regions, a protruding contact portion at least partially surrounded by the conductive line, and a vertical contact portion extending in the third direction between the contact surface and the protruding contact portion.

According to another aspect of the inventive concept, there is provided a semiconductor memory device including a conductive line extending lengthwise in a first direction, a plurality of channel regions arranged apart from each other in the first direction and spaced apart from the conductive line in a third direction, a plurality of contact plugs spaced apart from the conductive line in the third direction with the plurality of channel regions therebetween, a back gate electrode spaced apart from the conductive line in the third direction and extending lengthwise in a second direction between a first channel region and a second channel region, which are selected from the plurality of channel regions and are adjacent to each other, the first, second, and third directions being perpendicular with respect to each other, a back gate dielectric film arranged between the back gate electrode and the second channel region and contacting each of the back gate electrode and the second channel region, a word line spaced apart from the back gate electrode in the first direction with the second channel region therebetween, a gate dielectric film arranged between the word line and the second channel region and contacting each of the word line and the second channel region, and an epitaxial direct contact plug extending in the third direction between the first channel region and the conductive line, the epitaxial direct contact plug including a contact surface contacting the second channel region, a protruding contact portion at least partially surrounded by the conductive line, and a sidewall extending in the third direction between the contact surface and the protruding contact portion and contacting each of the back gate dielectric film and the gate dielectric film.

According to another aspect of the inventive concept, there is provided a semiconductor memory device including a plurality of conductive lines, which extend lengthwise in a first direction and are spaced apart from each other in a second direction, a plurality of contact plugs spaced apart from the plurality of conductive lines in a third direction, the first, second, and third directions being perpendicular with respect to each other, a plurality of channel regions arranged between the plurality of conductive lines and the plurality of contact plugs, the plurality of channel regions each having one end spaced apart from the plurality of conductive lines in the third direction and the other end connected to one contact plug selected from the plurality of contact plugs, a plurality of back gate electrodes, which are spaced apart from each other in the first direction and extend lengthwise in the second direction between the plurality of conductive lines and the plurality of contact plugs, a plurality of back gate dielectric films respectively contacting the plurality of back gate electrodes, a plurality of word lines extending lengthwise in the second direction between the plurality of conductive lines and the plurality of contact plugs, a plurality of gate dielectric films respectively contacting the plurality of word lines, and a plurality of epitaxial direct contact plugs extending in the third direction between the plurality of channel regions and the plurality of conductive lines, each of the plurality of epitaxial direct contact plugs including a contact surface contacting one channel region selected from the plurality of channel regions, a protruding contact portion at least partially surrounded by one conductive line selected from the plurality of conductive lines, and a sidewall that extends in the third direction between the contact surface and the protruding contact portion and is in contact with each of one back gate dielectric film selected from the plurality of back gate dielectric films and one gate dielectric film selected from the plurality of gate dielectric films.

### BRIEF DESCRIPTION OF THE DRAWINGS

Embodiments will be more clearly understood from the following detailed description taken in conjunction with the accompanying drawings in which:

FIG. 1 is a planar layout diagram illustrating some components of a semiconductor memory device according to some embodiments;

FIG. 2 is a cross-sectional view of the semiconductor memory device of FIG. 1, taken along a line X1-X1′ of FIG. 1;

FIG. 3 is an enlarged cross-sectional view of a region EX1 of FIG. 2;

FIGS. 4 to 10 are cross-sectional views each illustrating a semiconductor memory device according to some embodiments;

FIGS. 11A to 28B are diagrams respectively illustrating a sequence of processes of a method of fabricating a semiconductor memory device, according to some embodiments, and in particular, FIGS. 11A, 13A, 14A, 15A, 16A, 17A, 19A, 22A, 23A, and 28A are planar layout diagrams each illustrating some components of the semiconductor memory device, according to the sequence of processes, to illustrate example operations of the method of fabricating the semiconductor memory device, and FIGS. 11B, 12, 13B, 14B, 15B, 16B, 17B, 18, 19B, 20, 21, 22B, 23B, 24, 25, 26, 27, and 28B are cross-sectional views each illustrating a portion of the semiconductor memory device, which corresponds to the cross-section taken along the line X1-X1′ in FIG. 1, according to the sequence of processes; and

FIG. 29 is a cross-sectional view illustrating a method of fabricating a semiconductor memory device, according to some embodiments.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

It should be understood that, although the terms such as “first”, “second”, “third” and the like are used herein to describe various components, these components are not limited by these terms. These terms are used only to distinguish one component from another component, and it is a matter of course that a first component could be termed a second component or a third component and vice versa unless clearly stated otherwise. For example, a first channel region may be referred to as a second channel region or a third channel region without departing from the scope of the inventive concept, and similarly, a second channel region or a third channel region may be referred to as a first channel region. Although a first channel region, a second channel region, and a third channel region are each a channel region, the first channel region, the second channel region, and the third channel region are not the same channel region.

As used herein the terms horizontal and vertical refer to the orientation of a semiconductor device as illustrated in the drawings. For example, the X and Y directions in the drawings refer to horizontal directions and the Z direction in the drawings refers to a vertical direction.

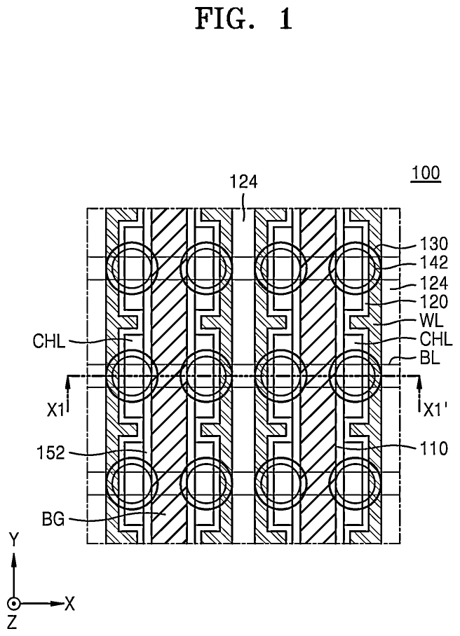

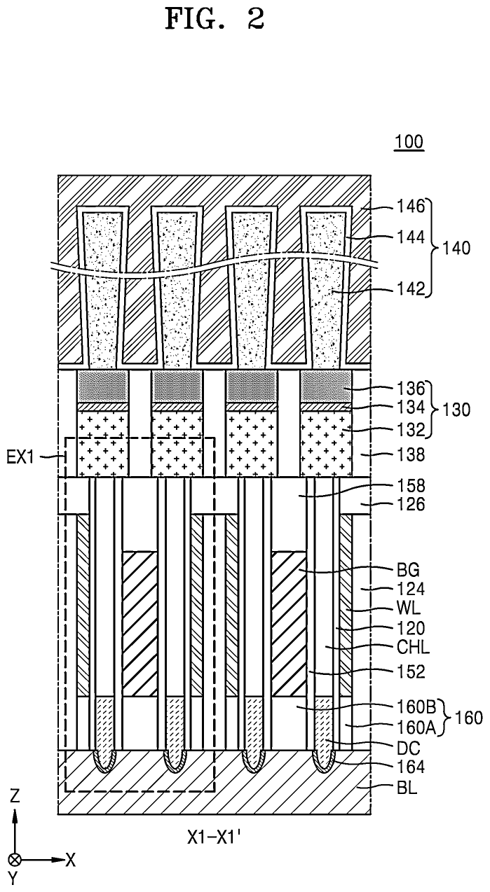

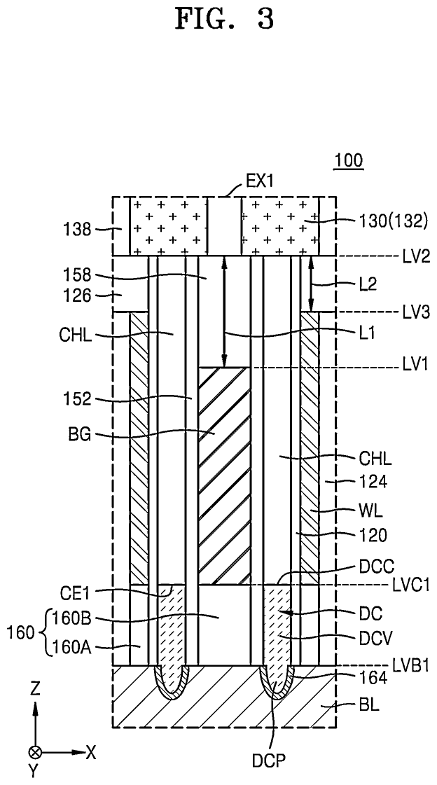

FIG. 1 is a planar layout diagram illustrating some components of a semiconductor memory device 100 according to some embodiments. FIG. 2 is a cross-sectional view of the semiconductor memory device 100, taken along a line X1-X1′ of FIG. 1, and FIG. 3 is an enlarged cross-sectional view of a region EX1 of FIG. 2.

Referring to FIGS. 1 to 3, the semiconductor memory device 100 may include a plurality of conductive lines BL extending lengthwise in a first horizontal direction (X direction) and repeatedly configured in a spaced apart arrangement from each other in a second horizontal direction (Y direction) that is perpendicular to the first horizontal direction (X direction). In the semiconductor memory device 100, each of the plurality of conductive lines BL may constitute a bit line.

A plurality of channel regions CHL may be arranged over each of the plurality of conductive lines BL, and a plurality of contact plugs 130 may be respectively arranged on the plurality of channel regions CHL. The plurality of channel regions CHL may be repeatedly arranged between the plurality of conductive lines BL and the plurality of contact plugs 130 and spaced apart from each other in the first horizontal direction (X direction) and the second horizontal direction (Y direction). Each of the plurality of channel regions CHL may have one end, which is spaced apart from the plurality of conductive lines BL in the vertical direction (Z direction), and the other end, which is electrically connected to one contact plug 130 selected from the plurality of contact plugs 130. Each of the plurality of channel regions CHL may be physically spaced apart from a conductive line BL and may be in contact with one contact plug 130

Each of the plurality of conductive lines BL may include a metal, a conductive metal nitride, doped polysilicon, or a combination thereof. For example, each of the plurality of conductive lines BL may include Ti, TiN, Ta, TaN, Mo, Ru, W, WN, Co, Ni, RuTiN, or a combination thereof.

The plurality of contact plugs 130 may be spaced apart from the plurality of conductive lines BL in the vertical direction (Z direction) with the plurality of channel regions CHL therebetween. The plurality of contact plugs 130 may be arranged in a matrix and spaced apart from each other in the first horizontal direction (X direction) and the second horizontal direction (Y direction). The plurality of contact plugs 130 may be respectively electrically connected to the plurality of channel regions CHL in one-to-one correspondence with the plurality of channel regions CHL.

Each of the plurality of contact plugs 130 may include a metal, a conductive metal nitride, a metal silicide, doped polysilicon, or a combination thereof. For example, each of the plurality of contact plugs 130 may include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof. In some embodiments, each of the plurality of contact plugs 130 may include a first conductive pattern 132, a second conductive pattern 134, and a third conductive pattern 136, which are sequentially stacked in the stated order on each of the plurality of channel regions CHL, as shown in FIG. 2. For example, although the first conductive pattern 132 may include doped polysilicon, the second conductive pattern 134 may include a metal silicide, and the third conductive pattern 136 may include a metal, embodiments of the inventive concept are not limited thereto.

As shown in FIG. 1, the plurality of channel regions CHL may include a first group of channel regions CHL, which are arranged in a line in the first horizontal direction (X direction) and spaced apart from each other in the first horizontal direction (X direction), and a second group of channel regions CHL, which are arranged in a line in the second horizontal direction (Y direction) and spaced apart from each other in the second horizontal direction (Y direction). Each of the plurality of contact plugs 130 may be arranged on one channel region CHL selected from the plurality of channel regions CHL. Each of the plurality of contact plugs 130 may pass through an interlayer dielectric 138 to contact the selected one channel region CHL. The interlayer dielectric 138 may include a silicon oxide film, a silicon nitride film, or a combination thereof.

In some embodiments, each of the plurality of channel regions CHL may include silicon, for example, single-crystal silicon, polycrystalline silicon, or amorphous silicon. In some embodiments, each of the plurality of channel regions CHL may include one or more materials, such as, for example, Ge, SiGe, SiC, GaAs, InAs, and/or InP. In some embodiments, the channel region CHL may include a conductive region, for example, an impurity-doped well or an impurity-doped structure.

A plurality of back gate electrodes BG and a plurality of word lines WL may be arranged over each of the plurality of conductive lines BL. The plurality of back gate electrodes BG and the plurality of word lines WL may each extend lengthwise in the second horizontal direction (Y direction) between the plurality of conductive lines BL and the plurality of contact plugs 130. The plurality of back gate electrodes BG may be spaced apart from each other in the first horizontal direction (X direction) and the plurality of word lines WL may be spaced apart from each other in the first horizontal direction (X direction).

In the plurality of back gate electrodes BG and the plurality of word lines WL, which are arranged in a line in the first horizontal direction (X direction) over one conductive line BL, one back gate electrode BG and a pair of word lines WL may be alternately arranged, and the one back gate electrode BG may be spaced apart from the pair of word lines WL with one channel region CHL therebetween. That is, the plurality of word lines WL may be arranged, such that a pair of adjacent word lines WL are arranged between each of the plurality of back gate electrodes BG.

Each of the plurality of back gate electrodes BG may include a metal, a conductive metal nitride, doped polysilicon, or a combination thereof. For example, each of the plurality of back gate electrodes BG may include, but is not limited to, Ti, TiN, Ta, TaN, Mo, Ru, W, WN, TiSiN, WSiN, doped polysilicon, or a combination thereof. Each of the plurality of word lines WL may include a metal, a conductive metal nitride, or a combination thereof. For example, each of the plurality of word lines WL may include, but is not limited to, Ti, TiN, Ta, TaN, Mo, Ru, W, WN, TiSiN, WSiN, or a combination thereof.

Each of the plurality of back gate electrodes BG may extend lengthwise in the second horizontal direction (Y direction) between two channel regions CHL that are adjacent to each other in the first horizontal direction (X direction). Each of the plurality of back gate electrodes BG may be spaced apart from the conductive line BL and each of the plurality of contact plugs 130 in the vertical direction (Z direction).

The semiconductor memory device 100 may include a plurality of back gate dielectric films 152 respectively on and at least partially covering the plurality of back gate electrodes BG. Each of the plurality of back gate dielectric films 152 may be arranged between one back gate electrode BG and one channel region CHL. Each of the plurality of back gate dielectric films 152 may be in contact with a back gate electrode BG and a channel region CHL, which are adjacent thereto. Each of the plurality of back gate dielectric films 152 may include one end contacting a conductive line BL and the other end contacting a contact plug 130.

In a region between a pair of adjacent channel regions CHL, a first capping insulating pattern 158 may be arranged between the back gate electrode BG and the plurality of contact plugs 130. In the region between the pair of adjacent channel regions CHL, a second capping insulating pattern 160B may be arranged between the back gate electrode BG and the conductive line BL. The first capping insulating pattern 158, the back gate electrode BG, and the second capping insulating pattern 160B may be arranged to at least partially overlap each other in the vertical direction (Z direction).

Each of the first capping insulating pattern 158 and the second capping insulating pattern 160B may include a silicon oxide film, a silicon nitride film, or a combination thereof. In some embodiments, the first capping insulating pattern 158 and the second capping insulating pattern 160B may include different materials relative to each other. For example, the first capping insulating pattern 158 may include a silicon oxide film and the second capping insulating pattern 160B may include a silicon nitride film. In some embodiments, the first capping insulating pattern 158 and the second capping insulating pattern 160B may include the same material. For example, the first capping insulating pattern 158 and the second capping insulating pattern 160B may include the same material selected from a silicon oxide film and a silicon nitride film.

Each of the plurality of word lines WL may be spaced apart from the conductive line BL and each of the plurality of contact plugs 130 in the vertical direction (Z direction). In the first horizontal direction (X direction), a pair of word lines WL may be arranged between each of the plurality of back gate electrodes BG. The pair of word lines WL may be spaced apart from, in the first horizontal direction (X direction), the back gate electrode BG adjacent thereto with one channel region CHL therebetween.

As shown in FIGS. 2 and 3, a plurality of epitaxial direct contact plugs DC may be respectively arranged between the conductive line BL and the plurality of channel regions CHL. Each of the plurality of epitaxial direct contact plugs DC may extend in the vertical direction (Z direction) between the conductive line BL and one channel region CHL selected from the plurality of channel regions CHL. Each of the plurality of epitaxial direct contact plugs DC may include a contact surface DCC contacting one channel region CHL from among the plurality of channel regions CHL, a protruding contact portion DCP at least partially surrounded by the conductive line BL, and a vertical contact portion DCV extending in the vertical direction (Z direction) between the contact surface DCC and the protruding contact portion DCP.

In some embodiments, each of the plurality of epitaxial direct contact plugs DC may include a semiconductor film doped with a dopant. The dopant may include an N-type dopant or a P-type dopant. The dopant may include, but is not limited to, P, B, and/or As. For example, each of the plurality of epitaxial direct contact plugs DC may include a silicon film doped with a dopant.

As shown in FIG. 3, a vertical level LVC1 of an end CE1, which is closest to the conductive line BL, of each of the plurality of channel regions CHL may be spaced apart from, in the vertical direction (Z direction), a vertical level LVB1 of a surface of the conductive line BL, which is closest to the back gate electrode BG.

The plurality of back gate electrodes BG and the plurality of word lines WL may each have an end surface facing the conductive line BL and that is closest to the conductive line BL, and a vertical level of the end surface of each of the plurality of back gate electrodes BG and the plurality of word lines WL may be spaced apart from, in the vertical direction (Z direction), the vertical level LVB1 of the surface of the conductive line BL, which is closest to the back gate electrode BG.

A vertical distance between the plurality of contact plugs 130 and a surface of the back gate electrode BG, which is closest to the plurality of contact plugs 130, may be greater than a vertical distance between the plurality of contact plugs 130 and a surface of the word line WL, which is closest to the plurality of contact plugs 130. A vertical distance L1 between a vertical level LV1 of the farthest portion of the back gate electrode BG from the conductive line BL in the vertical direction (Z direction) and a vertical level LV2 of the closest portion of the plurality of contact plugs 130 to the conductive line BL in the vertical direction (Z direction) may be greater than a vertical distance L2 between a vertical level LV3 of the farthest end of the word line WL from the conductive line BL and the vertical level LV2 set forth above. In the vertical direction (Z direction), the length of the first capping insulating pattern 158 may be greater than the length of a first gap-fill insulating pattern 126.

An isolation insulating pattern 124 may be arranged between a pair of word lines WL, which are arranged between a pair of adjacent channel regions CHL. The first gap-fill insulating pattern 126 may be arranged between the pair of word lines WL and the plurality of contact plugs 130, and a pair of second gap-fill insulating patterns 160A may be respectively arranged between the pair of word lines WL and the conductive line BL. The word line WL, the first gap-fill insulating pattern 126, and the second gap-fill insulating pattern 160A may be arranged between the pair of adjacent channel regions CHL to at least partially overlap each other in the vertical direction (Z direction). The pair of word lines WL may be spaced apart from the plurality of contact plugs 130 in the vertical direction (Z direction) with the first gap-fill insulating pattern 126 therebetween. The word line WL may be spaced apart from the conductive line BL with the second gap-fill insulating pattern 160A therebetween. In the vertical direction (Z direction), the length of the second gap-fill insulating pattern 160A may be equal or similar to the length of the second capping insulating pattern 160B. The second gap-fill insulating pattern 160A and the second capping insulating pattern 160B may constitute a gap-fill structure 160 that is in contact with the conductive line BL.

Each of the isolation insulating pattern 124, the first gap-fill insulating pattern 126, and the second gap-fill insulating pattern 160A may include a silicon oxide film, a silicon nitride film, or a combination thereof. In some embodiments, the isolation insulating pattern 124, the first gap-fill insulating pattern 126, and the second gap-fill insulating pattern 160A may respectively include materials that are identical or similar to each other. In some embodiments, at least one of the isolation insulating pattern 124, the first gap-fill insulating pattern 126, and the second gap-fill insulating pattern 160A may include a different material from the others. For example, each of the isolation insulating pattern 124, the first gap-fill insulating pattern 126, and the second gap-fill insulating pattern 160A may include, but is not limited to, a silicon nitride film.

A gate dielectric film 120 may be arranged between each of the plurality of word lines WL and the channel region CHL adjacent thereto. A pair of gate dielectric films 120 may be arranged between a pair of adjacent channel regions CHL, and a pair of word lines WL may be arranged between the pair of gate dielectric films 120. Each of the pair of gate dielectric films 120 may include one end, which is in contact with the conductive line BL, and the other end, which is in contact with one contact plug 130 selected from the plurality of contact plugs 130.

One sidewall of the vertical contact portion DCV of each of the plurality of epitaxial direct contact plugs DC in terms of the first horizontal direction (X direction) may be in contact with a back gate dielectric film 152, and the other sidewall of the vertical contact portion DCV of each of the plurality of epitaxial direct contact plugs DC in terms of the first horizontal direction (X direction) may be in contact with a gate dielectric film 120. The width of the vertical contact portion DCV of each of the plurality of epitaxial direct contact plugs DC in the first horizontal direction (X direction) may be defined by the back gate dielectric film 152 and the gate dielectric film 120. The protruding contact portion DCP of each of the plurality of epitaxial direct contact plugs DC may further protrude toward the conductive line BL than the back gate dielectric film 152 and the gate dielectric film 120.

In some embodiments, the width of at least a portion of the protruding contact portion DCP of each of the plurality of epitaxial direct contact plugs DC in the first horizontal direction (X direction) may be less than the width of the vertical contact portion DCV of each of the plurality of epitaxial direct contact plugs DC in the first horizontal direction (X direction).

A metal silicide film 164 may be arranged between the protruding contact portion DCP of each of the plurality of epitaxial direct contact plugs DC and the conductive line BL. The metal silicide film 164 may include, but is not limited to, TiSi, WSi, TaSi, CoSi, NiSi, or a combination thereof.

In some embodiments, each of the gate dielectric film 120 and the back gate dielectric film 152 may include a silicon oxide film, a high-K film, or a combination thereof. The high-K film refers to a film having a dielectric constant, which is higher than that of a silicon oxide film. In some embodiments, each of the gate dielectric film 120 and the back gate dielectric film 152 may include one or more materials, such as, for example, silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO)), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and/or lead scandium tantalum oxide (PbScTaO). The plurality of back gate electrodes BG, the plurality of word lines WL, the plurality of channel regions CHL, the plurality of back gate dielectric films 152, and the plurality of gate dielectric films 120, which are arranged between the plurality of conductive lines BL and the plurality of contact plugs 130, may constitute a plurality of vertical channel transistors.

As shown in FIGS. 1 and 2, a capacitor structure 140 may be arranged on the plurality of contact plugs 130 and the interlayer dielectric 138. The capacitor structure 140 may include a plurality of lower electrodes 142, a capacitor dielectric film 144 conformally on and at least partially covering the surface of each of the plurality of lower electrodes 142, and an upper electrode 146 on and at least partially covering the plurality of lower electrodes 142 with the capacitor dielectric film 144 therebetween. Each of the plurality of lower electrodes 142 may be connected to the channel region CHL via one contact plug 130 selected from the plurality of contact plugs 130. The third conductive pattern 136 of each of the plurality of contact plugs 130 may function as a landing pad with which one lower electrode 142 selected from the plurality of lower electrodes 142 is in contact.

The semiconductor memory device 100 described with reference to FIGS. 1 to 3 includes the plurality of epitaxial direct contact plugs DC, which are contact structures that may be formed by a relatively low-temperature process, for example, a process performed at a temperature selected from a range of room temperature to about 480° C., during the process of fabricating the semiconductor memory device 100. Therefore, according to embodiments of the inventive concept, thermal damage to unit devices in the semiconductor memory device 100 may be reduced or prevented and the semiconductor memory device 100 having a structure with improved reliability may be provided. In addition, according to embodiments of the inventive concept, each of the plurality of epitaxial direct contact plugs DC includes the protruding contact portion DCP at least partially surrounded by the conductive line BL. Therefore, each of the plurality of epitaxial direct contact plugs DC may have an increased contact area that may be electrically connected to the conductive line BL via the metal silicide film 164. As such, the protruding contact portion DCP of each of the plurality of epitaxial direct contact plugs DC may provide a relatively large contact area, thereby providing a semiconductor memory device 100 having a structure with improved electrical characteristics.

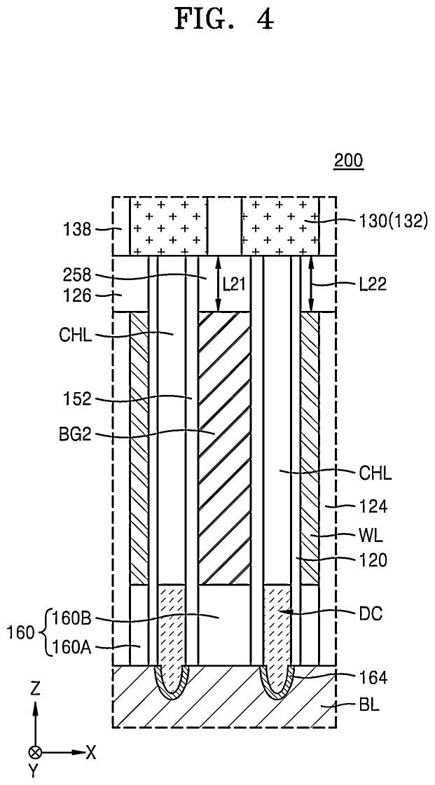

FIG. 4 is a cross-sectional view illustrating a semiconductor memory device 200 according to some embodiments. FIG. 4 illustrates an enlarged cross-sectional configuration of a portion of the semiconductor memory device 200, which corresponds to the region EX1 of FIG. 2. In FIG. 4, the same reference numerals as in FIGS. 1 to 3 respectively denote the same members, and here, repeated descriptions thereof are omitted.

Referring to FIG. 4, the semiconductor memory device 200 has substantially the same configuration as the semiconductor memory device 100 described with reference to FIGS. 1 and 3. However, the semiconductor memory device 200 may include a back gate electrode BG2 and a first capping insulating pattern 258.

The back gate electrode BG2 and the first capping insulating pattern 258 may have substantially the same configurations as the back gate electrode BG and the first capping insulating pattern 158 described with reference to FIGS. 1 and 3, respectively. However, a first vertical distance L21 from the vertical level of the plurality of contact plugs 130 to the back gate electrode BG2 may be equal or similar to a second vertical distance L22 from the vertical level of the plurality of contact plugs 130 to the word line WL. In the vertical direction (Z direction), the length of the first capping insulating pattern 258 may be equal or similar to the length of the first gap-fill insulating pattern 126.

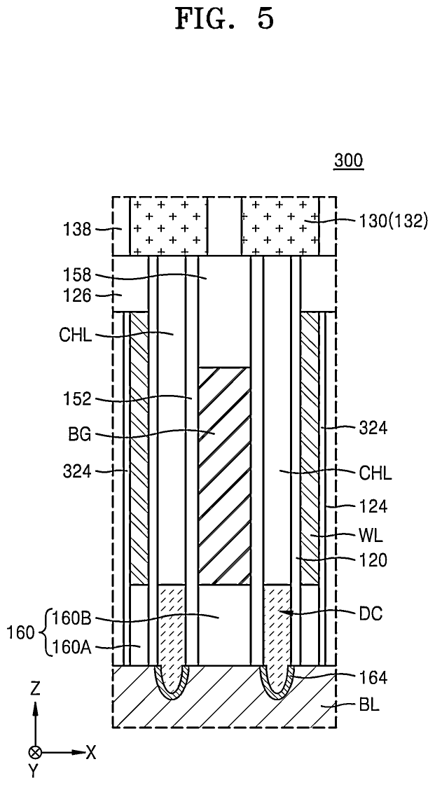

FIG. 5 is a cross-sectional view illustrating a semiconductor memory device 300 according to some embodiments. FIG. 5 illustrates an enlarged cross-sectional configuration of a portion of the semiconductor memory device 300, which corresponds to the region EX1 of FIG. 2. In FIG. 5, the same reference numerals as in FIGS. 1 to 3 respectively denote the same members, and here, repeated descriptions thereof are omitted.

Referring to FIG. 5, the semiconductor memory device 300 has substantially the same configuration as the semiconductor memory device 100 described with reference to FIGS. 1 and 3. However, the semiconductor memory device 300 may further include a spacer insulating pattern 324 between the word line WL and the isolation insulating pattern 124. In the first horizontal direction (X direction), the width of the spacer insulating pattern 324 may be less than the width of the isolation insulating pattern 124.

In some embodiments, the spacer insulating pattern 324 and the isolation insulating pattern 124 may include the same material. In some embodiments, the spacer insulating pattern 324 and the isolation insulating pattern 124 may include different materials relative to each other. In some embodiments, each of the spacer insulating pattern 324 and the isolation insulating pattern 124 may include one or more materials, such as, for example, silicon nitride (SiN), silicon oxynitride (SiON), silicon carbonitride (SiCN), silicon oxycarbonitride (SiOCN), and/or silicon boron nitride (SiBN), but embodiments of the inventive concept are not limited to the materials set forth above.

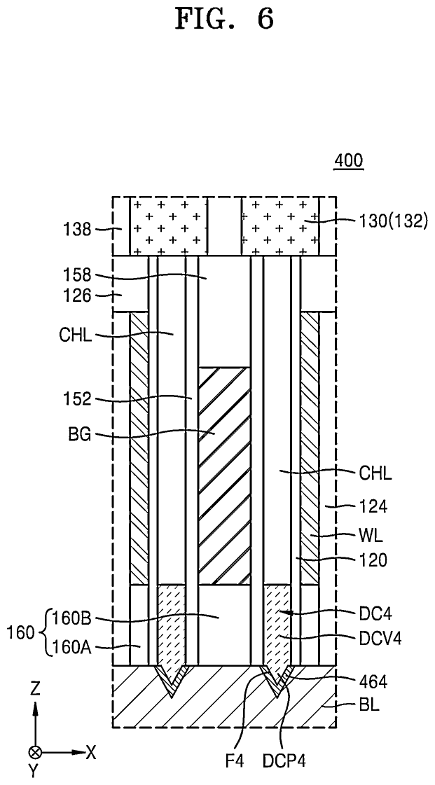

FIG. 6 is a cross-sectional view illustrating a semiconductor memory device 400 according to some embodiments. FIG. 6 illustrates an enlarged cross-sectional configuration of a portion of the semiconductor memory device 400, which corresponds to the region EX1 of FIG. 2. In FIG. 6, the same reference numerals as in FIGS. 1 to 3 respectively denote the same members, and here, repeated descriptions thereof are omitted.

Referring to FIG. 6, the semiconductor memory device 400 has substantially the same configuration as the semiconductor memory device 100 described with reference to FIGS. 1 and 3. However, the semiconductor memory device 400 includes a plurality of epitaxial direct contact plugs DC4 instead of the plurality of epitaxial direct contact plugs DC. The plurality of epitaxial direct contact plugs DC4 have substantially the same configuration as the plurality of epitaxial direct contact plugs DC described with reference to FIGS. 1 and 3. However, each of the plurality of epitaxial direct contact plugs DC4 includes a protruding contact portion DCP4 that protrudes toward the conductive line BL. The protruding contact portion DCP4 may have a facet surface F4, which is grown in the crystal direction of a semiconductor film constituting an epitaxial direct contact plug DC4, and have a cross-sectional shape that may approximate a triangle. The facet surface F4 of the protruding contact portion DCP4 may include an inclined surface that is inclined with respect to each of the first horizontal direction (X direction) and the vertical direction (Z direction). The width of at least a portion of the protruding contact portion DCP4 of each of the plurality of epitaxial direct contact plugs DC4 in the first horizontal direction (X direction) may be less than the width of a vertical contact portion DCV4 of each of the plurality of epitaxial direct contact plugs DC4 in the first horizontal direction (X direction).

A metal silicide film 464 may be arranged between the protruding contact portion DCP4 of each of the plurality of epitaxial direct contact plugs DC4 and the conductive line BL. A more detailed configuration of the metal silicide film 464 is substantially the same as that of the metal silicide film 164 described with reference to FIGS. 2 and 3.

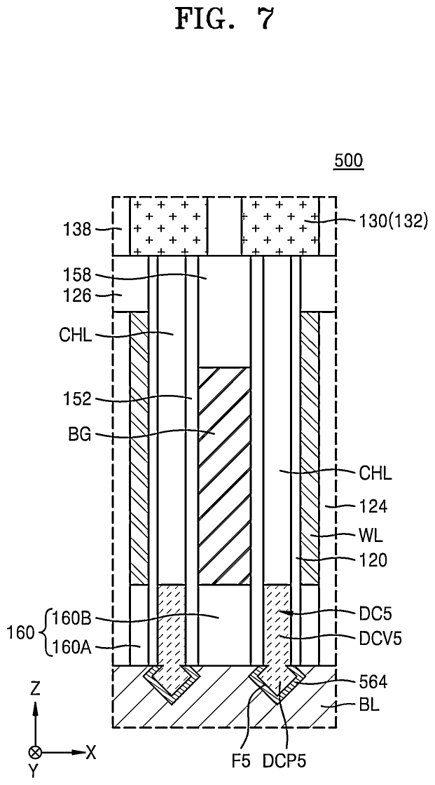

FIG. 7 is a cross-sectional view illustrating a semiconductor memory device 500 according to some embodiments. FIG. 7 illustrates an enlarged cross-sectional configuration of a portion of the semiconductor memory device 500, which corresponds to the region EX1 of FIG. 2. In FIG. 7, the same reference numerals as in FIGS. 1 to 3 respectively denote the same members, and here, repeated descriptions thereof are omitted.

Referring to FIG. 7, the semiconductor memory device 500 has substantially the same configuration as the semiconductor memory device 100 described with reference to FIGS. 1 and 3. However, the semiconductor memory device 500 includes a plurality of epitaxial direct contact plugs DC5 instead of the plurality of epitaxial direct contact plugs DC. The plurality of epitaxial direct contact plugs DC5 have substantially the same configuration as the plurality of epitaxial direct contact plugs DC described with reference to FIGS. 1 and 3. However, each of the plurality of epitaxial direct contact plugs DC5 includes a protruding contact portion DCP5 that protrudes toward the conductive line BL. The protruding contact portion DCP5 may have a facet surface F5, which is grown in the crystal direction of a semiconductor film constituting an epitaxial direct contact plug DC5, and have a cross-sectional shape that may approximate a quadrangle. The facet surface F5 of the protruding contact portion DCP5 may include an inclined surface that is inclined with respect to each of the first horizontal direction (X direction) and the vertical direction (Z direction). The width of a portion of the protruding contact portion DCP5 of each of the plurality of epitaxial direct contact plugs DC5 in the first horizontal direction (X direction) may be greater than the width of a vertical contact portion DCV5 of each of the plurality of epitaxial direct contact plugs DC5 in the first horizontal direction (X direction). The width of another portion of the protruding contact portion DCP5 of each of the plurality of epitaxial direct contact plugs DC5 in the first horizontal direction (X direction) may be less than the width of the vertical contact portion DCV5 of each of the plurality of epitaxial direct contact plugs DC5 in the first horizontal direction (X direction).

A metal silicide film 564 may be arranged between the protruding contact portion DCP5 of each of the plurality of epitaxial direct contact plugs DC5 and the conductive line BL. A more detailed configuration of the metal silicide film 564 is substantially the same as that of the metal silicide film 164 described with reference to FIGS. 2 and 3.

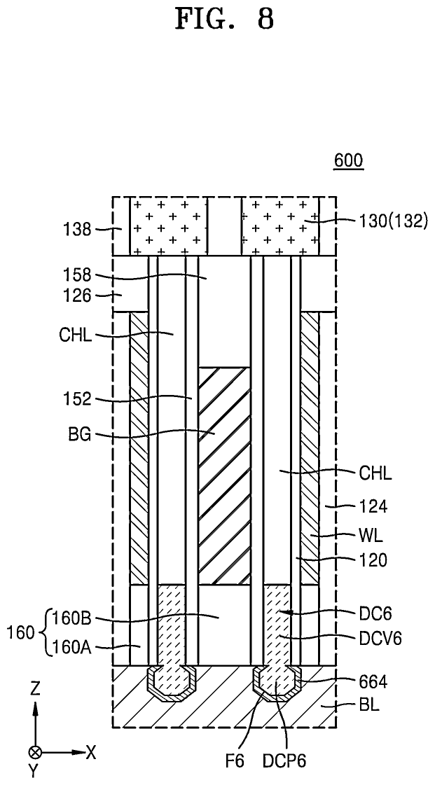

FIG. 8 is a cross-sectional view illustrating a semiconductor memory device 600 according to some embodiments. FIG. 8 illustrates an enlarged cross-sectional configuration of a portion of the semiconductor memory device 600, which corresponds to the region EX1 of FIG. 2. In FIG. 8, the same reference numerals as in FIGS. 1 to 3 respectively denote the same members, and here, repeated descriptions thereof are omitted.

Referring to FIG. 8, the semiconductor memory device 600 has substantially the same configuration as the semiconductor memory device 100 described with reference to FIGS. 1 and 3. However, the semiconductor memory device 600 includes a plurality of epitaxial direct contact plugs DC6 instead of the plurality of epitaxial direct contact plugs DC. The plurality of epitaxial direct contact plugs DC6 have substantially the same configuration as the plurality of epitaxial direct contact plugs DC described with reference to FIGS. 1 and 3. However, each of the plurality of epitaxial direct contact plugs DC6 includes a protruding contact portion DCP6 that protrudes toward the conductive line BL. The protruding contact portion DCP6 may have a facet surface F6, which is grown in the crystal direction of a semiconductor film constituting an epitaxial direct contact plug DC6, and have a cross-sectional shape that may approximate an octagon. The facet surface F6 of the protruding contact portion DCP6 may include an inclined surface that is inclined with respect to each of the first horizontal direction (X direction) and the vertical direction (Z direction). The width of a portion of the protruding contact portion DCP6 of each of the plurality of epitaxial direct contact plugs DC6 in the first horizontal direction (X direction) may be greater than the width of a vertical contact portion DCV6 of each of the plurality of epitaxial direct contact plugs DC6 in the first horizontal direction (X direction). The width of another portion of the protruding contact portion DCP6 of each of the plurality of epitaxial direct contact plugs DC6 in the first horizontal direction (X direction) may be less than the width of the vertical contact portion DCV6 of each of the plurality of epitaxial direct contact plugs DC6 in the first horizontal direction (X direction).

A metal silicide film 664 may be arranged between the protruding contact portion DCP6 of each of the plurality of epitaxial direct contact plugs DC6 and the conductive line BL. A more detailed configuration of the metal silicide film 664 is substantially the same as that of the metal silicide film 164 described with reference to FIGS. 2 and 3.

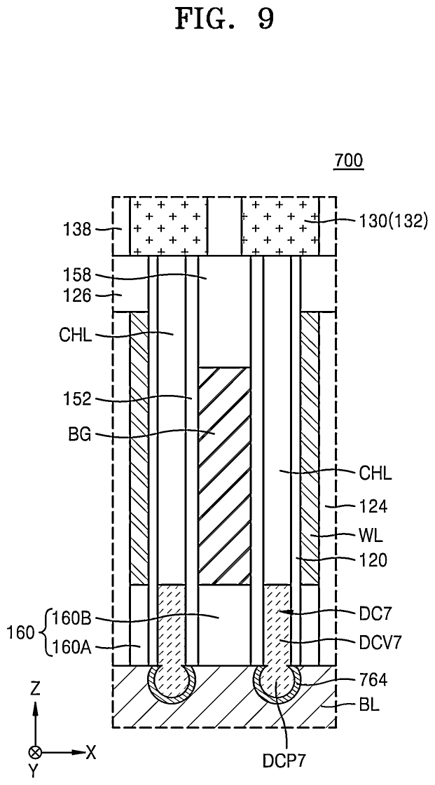

FIG. 9 is a cross-sectional view illustrating a semiconductor memory device 700 according to some embodiments. FIG. 9 illustrates an enlarged cross-sectional configuration of a portion of the semiconductor memory device 700, which corresponds to the region EX1 of FIG. 2. In FIG. 9, the same reference numerals as in FIGS. 1 to 3 respectively denote the same members, and here, repeated descriptions thereof are omitted.

Referring to FIG. 9, the semiconductor memory device 700 has substantially the same configuration as the semiconductor memory device 100 described with reference to FIGS. 1 and 3. However, the semiconductor memory device 700 includes a plurality of epitaxial direct contact plugs DC7 instead of the plurality of epitaxial direct contact plugs DC. The plurality of epitaxial direct contact plugs DC7 have substantially the same configuration as the plurality of epitaxial direct contact plugs DC described with reference to FIGS. 1 and 3. However, each of the plurality of epitaxial direct contact plugs DC6 includes a protruding contact portion DCP7 that protrudes toward the conductive line BL. The protruding contact portion DCP7 may have a cross-sectional shape that may approximate a circle. The width of a portion of the protruding contact portion DCP7 of each of the plurality of epitaxial direct contact plugs DC7 in the first horizontal direction (X direction) may be greater than the width of a vertical contact portion DCV7 of each of the plurality of epitaxial direct contact plugs DC7 in the first horizontal direction (X direction). The width of another portion of the protruding contact portion DCP7 of each of the plurality of epitaxial direct contact plugs DC7 in the first horizontal direction (X direction) may be less than the width of the vertical contact portion DCV7 of each of the plurality of epitaxial direct contact plugs DC7 in the first horizontal direction (X direction).

A metal silicide film 764 may be arranged between the protruding contact portion DCP7 of each of the plurality of epitaxial direct contact plugs DC7 and the conductive line BL. A more detailed configuration of the metal silicide film 764 is substantially the same as that of the metal silicide film 164 described with reference to FIGS. 2 and 3.

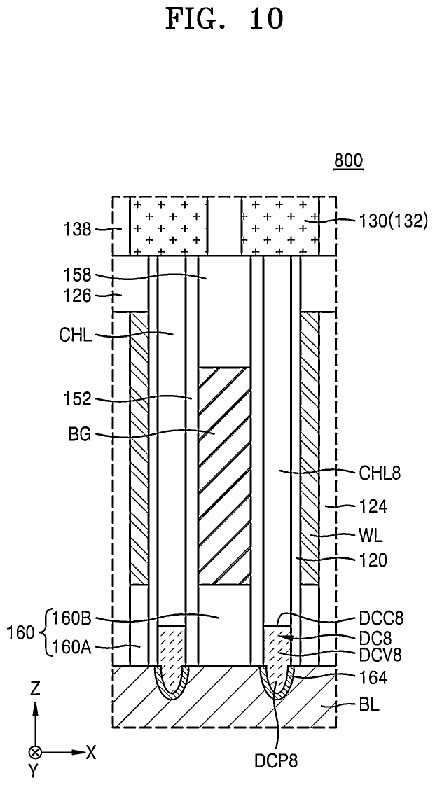

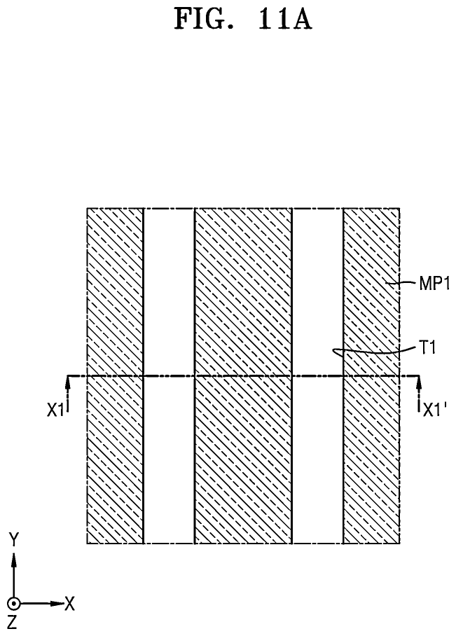

FIG. 10 is a cross-sectional view illustrating a semiconductor memory device 800 according to some embodiments. FIG. 10 illustrates an enlarged cross-sectional configuration of a portion of the semiconductor memory device 800, which corresponds to the region EX1 of FIG. 2. In FIG. 10, the same reference numerals as in FIGS. 1 to 3 respectively denote the same members, and here, repeated descriptions thereof are omitted.

Referring to FIG. 10, the semiconductor memory device 800 has substantially the same configuration as the semiconductor memory device 100 described with reference to FIGS. 1 and 3. However, the semiconductor memory device 800 includes a channel region CHL8 instead of the channel region CHL and include a plurality of epitaxial direct contact plugs DC8 instead of the plurality of epitaxial direct contact plugs DC.

The channel region CHL8 may have a shape further protruding toward the conductive line BL than the back gate electrode BG and the word line WL. The plurality of epitaxial direct contact plugs DC8 have substantially the same configuration as the plurality of epitaxial direct contact plugs DC described with reference to FIGS. 1 and 3. However, each of the plurality of epitaxial direct contact plugs DC8 may include a contact surface DCC8 contacting the channel region CHL8, a protruding contact portion DCP8 surrounded by the conductive line BL, and a vertical contact portion DCV8 extending in the vertical direction (Z direction) between the contact surface DCC8 and the protruding contact portion DCP8. The contact surface DCC8 of the epitaxial direct contact plug DC8 may be closer to the conductive line BL than the back gate electrode BG and the word line WL.

The semiconductor memory devices 200, 300, 400, 500, 600, 700, and 800 described with reference to FIGS. 4 to 10 respectively include the plurality of epitaxial direct contact plugs DC, DC4, DC5, DC6, DC7, and DC8, which are contact structures that may be formed by a relatively low-temperature process, for example, a process performed at a temperature selected from a range of room temperature to about 480° C., during the process of fabricating each of the semiconductor memory devices 200, 300, 400, 500, 600, 700, and 800. Therefore, according to embodiments of the inventive concept, thermal damage to unit devices in each of the semiconductor memory devices 200, 300, 400, 500, 600, 700, and 800 may be reduced or prevented and the semiconductor memory devices 200, 300, 400, 500, 600, 700, and 800 each having a structure with improved reliability may be provided. In addition, according to embodiments of the inventive concept, the plurality of epitaxial direct contact plugs DC, DC4, DC5, DC6, DC7, and DC8 respectively include the protruding contact portions DCP, DCP4, DCP5, DCP6, DCP7, and DCP8 at least partially surrounded by the conductive line BL. Therefore, each epitaxial direct contact plug DC, DC4, DC5, DC6, DC7, or DC8 may have an increased contact area that may be electrically connected with the conductive line BL via the metal silicide film 164, 464, 564, 664, or 764. As such, because the protruding contact portion DCP, DCP4, DCP5, DCP6, DCP7, or DCP8 of each epitaxial direct contact plug DC, DC4, DC5, DC6, DC7, or DC8 provides a relatively large contact area, the semiconductor memory devices 200, 300, 400, 500, 600, 700, and 800 each having a structure with improved electrical characteristics may be provided. Next, a method of fabricating a semiconductor memory device, according to some embodiments, is described by way of a specific example.

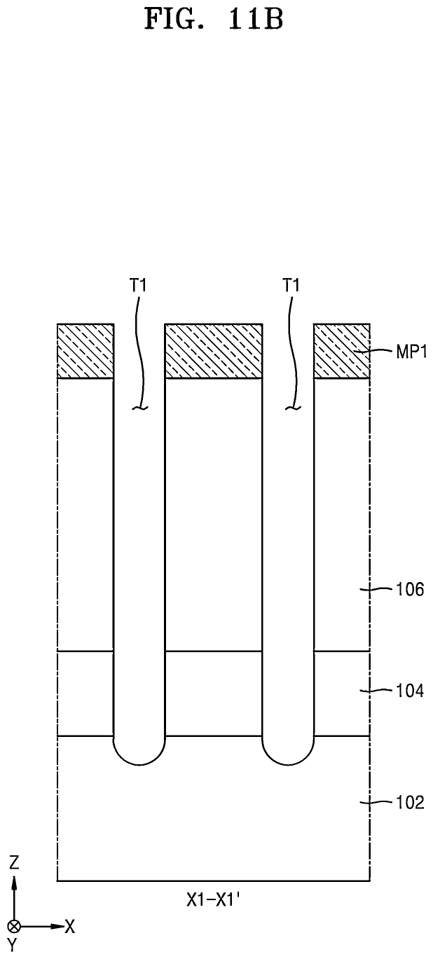

FIGS. 11A to 28B are diagrams respectively illustrating a sequence of processes of a method of fabricating a semiconductor memory device, according to some embodiments. More specifically, FIGS. 11A, 13A, 14A, 15A, 16A, 17A, 19A, 22A, 23A, and 28A are planar layout diagrams each illustrating some components of the semiconductor memory device, according to the sequence of processes, to describe an example method of fabricating the semiconductor memory device. FIGS. 11B, 12, 13B, 14B, 15B, 16B, 17B, 18, 19B, 20, 21, 22B, 23B, 24, 25, 26, 27, and 28B are cross-sectional views each illustrating a portion of the semiconductor memory device, which corresponds to the cross-section taken along the line X1-X1′in FIG. 1, according to the sequence of processes, and here, FIGS. 11B, 13B, 14B, 15B, 16B, 17B, 19B, 22B, 23B, and 28B are cross-sectional views respectively taken along the lines X1-X1′ of FIGS. 11A, 13A, 14A, 15A, 16A, 17A, 19A, 22A, 23A, and 28A. An example of a method of fabricating the semiconductor memory device 100 shown in FIGS. 1 to 3 is described with reference to FIGS. 11A to 28B. In FIGS. 11A to 28B, the same reference numerals as in FIGS. 1 to 3 respectively denote the same members, and here, repeated descriptions thereof are omitted.

Referring to FIGS. 11A and 11B, a substrate structure including a substrate 102, a gap-fill insulating layer 104, and an active layer 106 may be prepared.

The substrate structure may include a silicon-on-insulator (SOI) substrate. The substrate 102 may include a silicon substrate. The gap-fill insulating layer 104 may include a silicon oxide film. The active layer 106 may include one or more materials, such as, for example, Ge, SiGe, SiC, GaAs, InAs, and/or InP. In some embodiments, the active layer 106 may include an impurity-doped well or an impurity-doped structure.

A mask pattern MP1 may be formed on the active layer 106 of the substrate structure. The mask pattern MP1 may include a silicon nitride film. In some embodiments, an oxide film may be arranged between the active layer 106 and the mask pattern MP1.

Portions of the substrate structure may be etched by using the mask pattern MP1 as an etch mask, thereby forming a plurality of first trenches T1. The plurality of first trenches T1 may be formed to pass through the active layer 106 and the gap-fill insulating layer 104 in the vertical direction (Z direction) and to extend lengthwise in the second horizontal direction (Y direction).

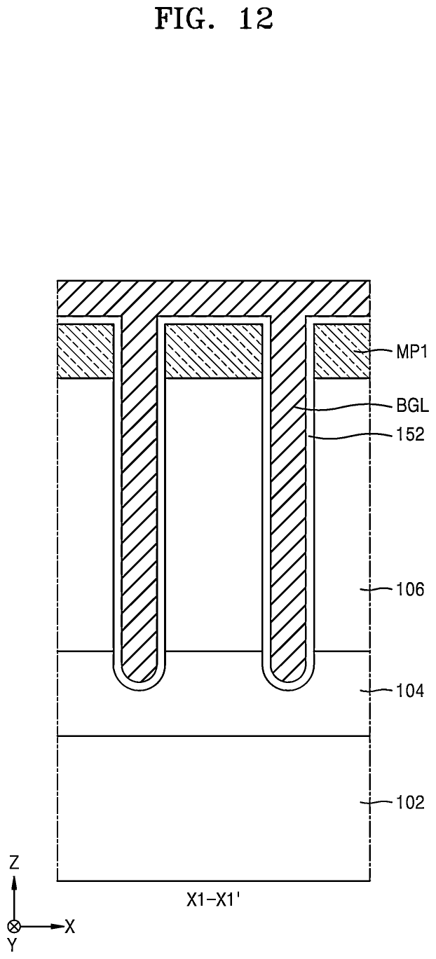

Referring to FIG. 12, in the resulting product of FIGS. 11A and 11B, a back gate dielectric film 152, which conformally at least partially covers inner walls of the plurality of first trenches T1 and the surface of each mask pattern MP1, and a back gate conductive layer BGL, which is arranged on the back gate dielectric film 152 to at least partially fill the plurality of first trenches T1, may be formed. A constituent material of the back gate conductive layer BGL may be substantially the same as the constituent material of the back gate electrode BG described above.

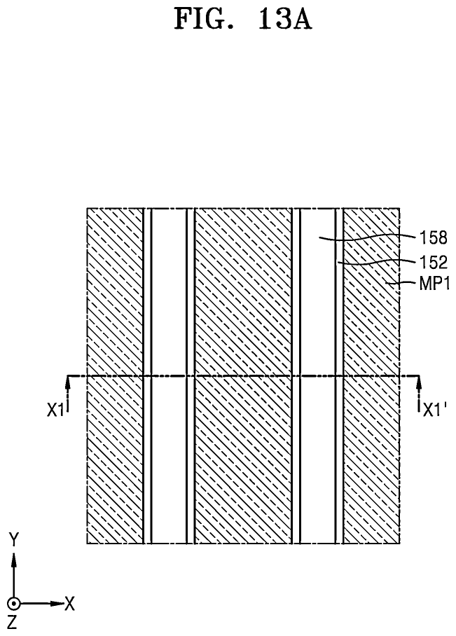

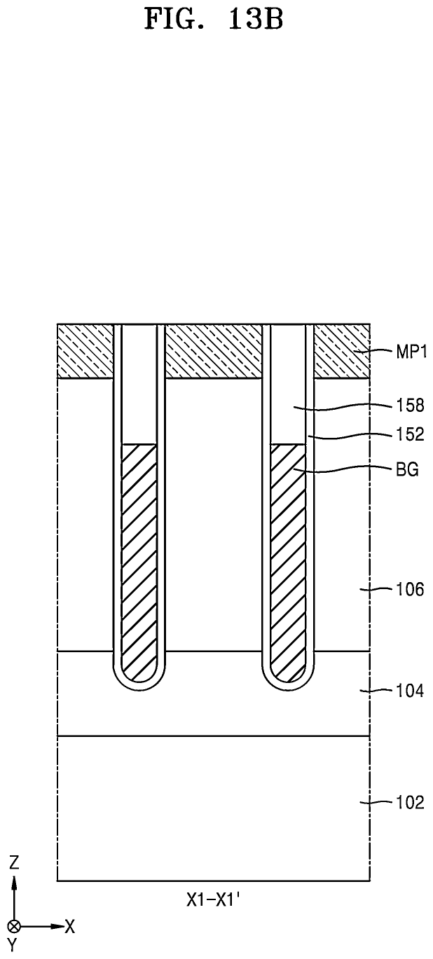

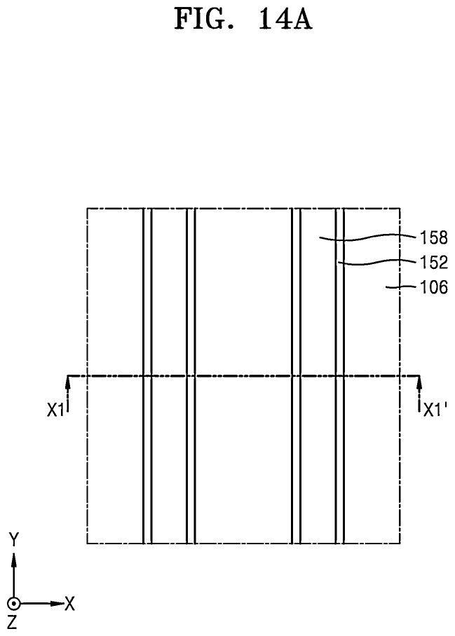

Referring to FIGS. 13A and 13B, in the resulting product of FIG. 12, the back gate conductive layer BGL may be etched-back to respectively form a plurality of back gate electrodes BG in the plurality of first trenches T1, followed by at least partially filling an upper space of each of the plurality of first trenches T1 with a first capping insulating pattern 158, and then, a resulting product obtained as a result may be planarized, thereby at least partially exposing the upper surface of the mask pattern MP1.

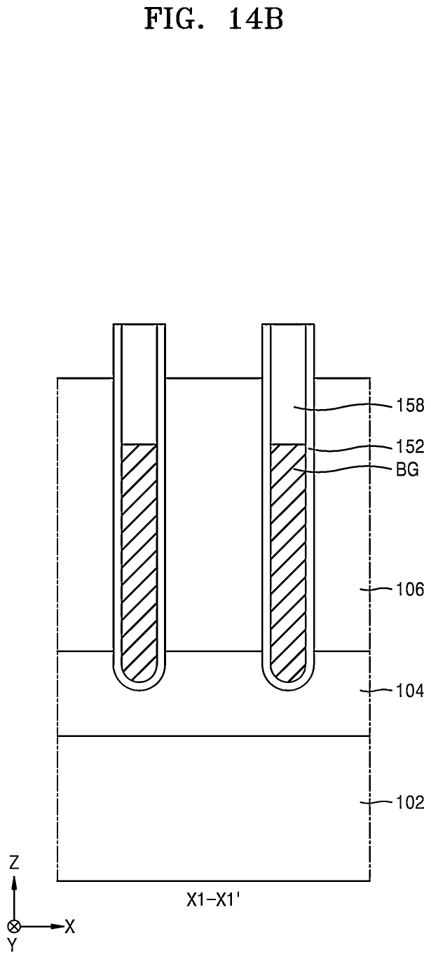

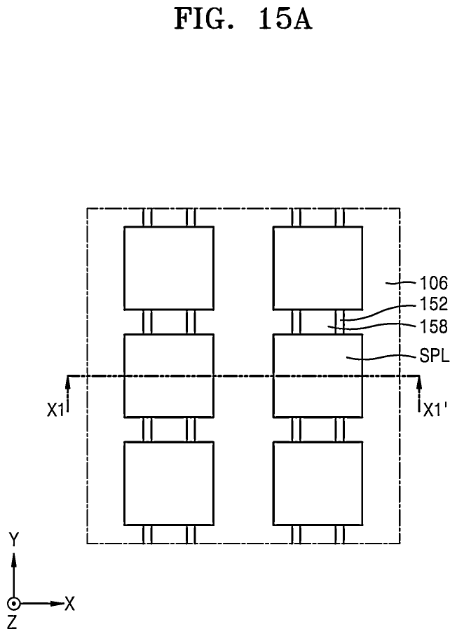

Referring to FIGS. 14A and 14B, the mask pattern MP1 may be removed from the resulting product of FIGS. 13A and 13B, thereby at least partially exposing the active layer 106 around a plurality of first capping insulating patterns 158 and a plurality of back gate dielectric films 152.

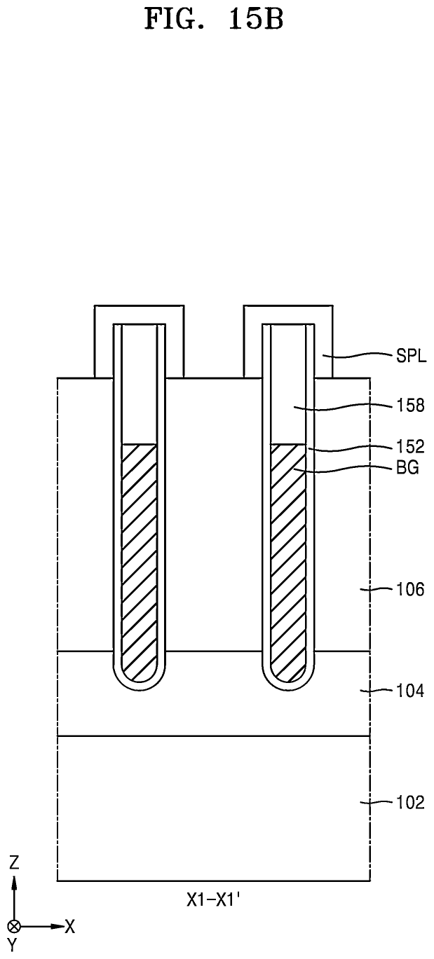

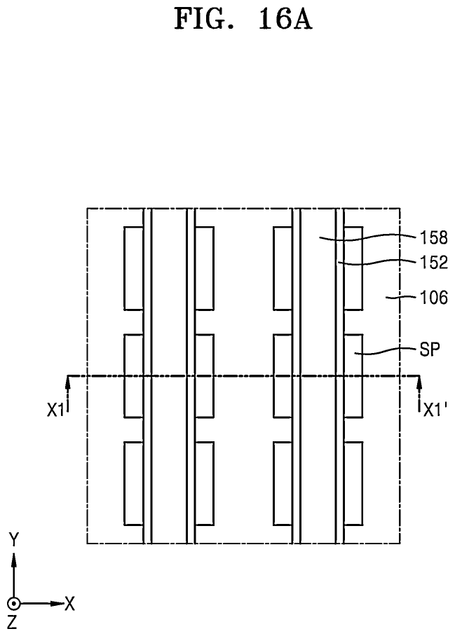

Referring to FIGS. 15A and 15B, a plurality of spacer layers SPL may be formed to be on and at least partially cover a portion of each of the plurality of first capping insulating patterns 158 and the plurality of back gate dielectric films 152 and a portion of the active layer 106 around each thereof. Each of the plurality of spacer layers SPL may include a silicon oxide film. The plurality of spacer layers SPL may include a first group of spacer layers SPL, which are arranged in a line in the first horizontal direction (X direction) and spaced apart from each other in the first horizontal direction (X direction), and a second group of spacer layers SPL, which are arranged in a line in the second horizontal direction (Y direction) and spaced apart from each other in the second horizontal direction (Y direction).

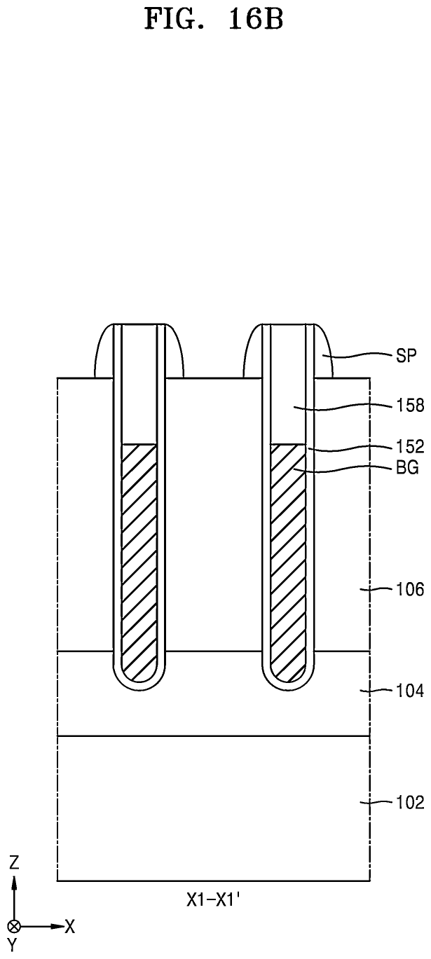

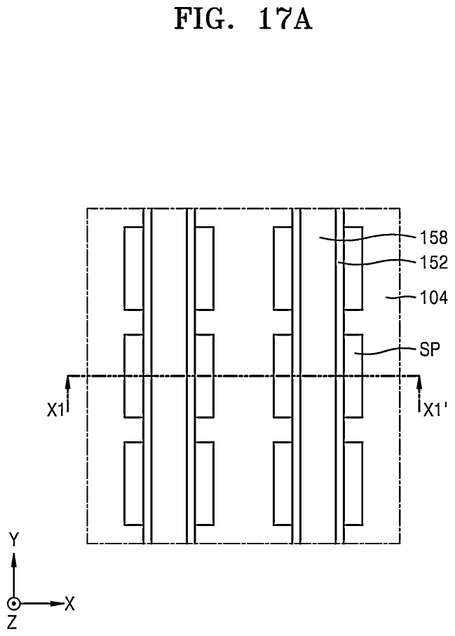

Referring to FIGS. 16A and 16B, the plurality of spacer layers SPL may be etched-back, thereby forming a plurality of spacers SP, which respectively at least partially cover both sidewalls of each of a plurality of structures in terms of the first horizontal direction (X direction), each of the plurality of structures including the first capping insulating pattern 158 and the back gate dielectric film 152. Portions of the upper surface of the active layer 106, which are adjacent to each of the plurality of structures, may be respectively at least partially covered by the plurality of spacers SP.

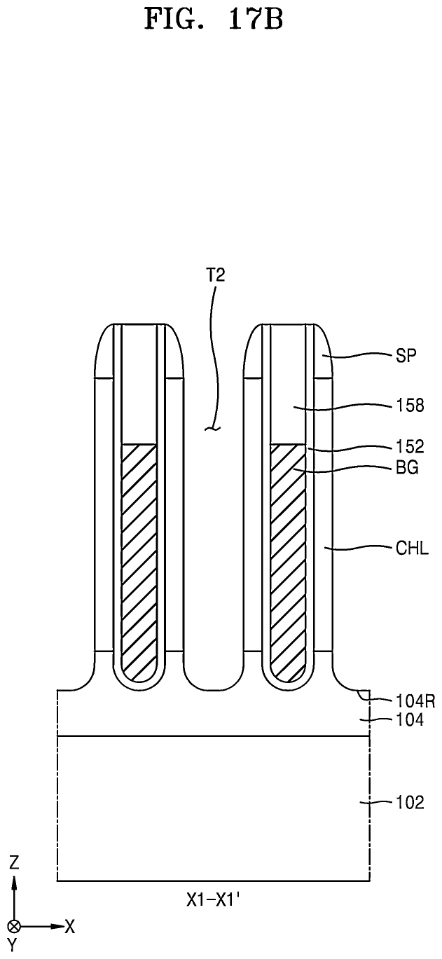

Referring to FIGS. 17A and 17B, the active layer 106 may be etched by using the plurality of first capping insulating patterns 158, the plurality of back gate dielectric films 152, and the plurality of spacers SP as an etch mask, thereby forming a plurality of second trenches T2. As a result, portions of the active layer 106, which are respectively located under the plurality of spacers SP, may remain as a plurality of channel regions CHL, respectively. The gap-fill insulating layer 104 may be partially etched due to over-etching during the process of etching the active layer 106, and thus, a plurality of recess regions 104R may be formed in the upper surface of the gap-fill insulating layer 104 and may be respectively electrically connected to the plurality of second trenches T2.

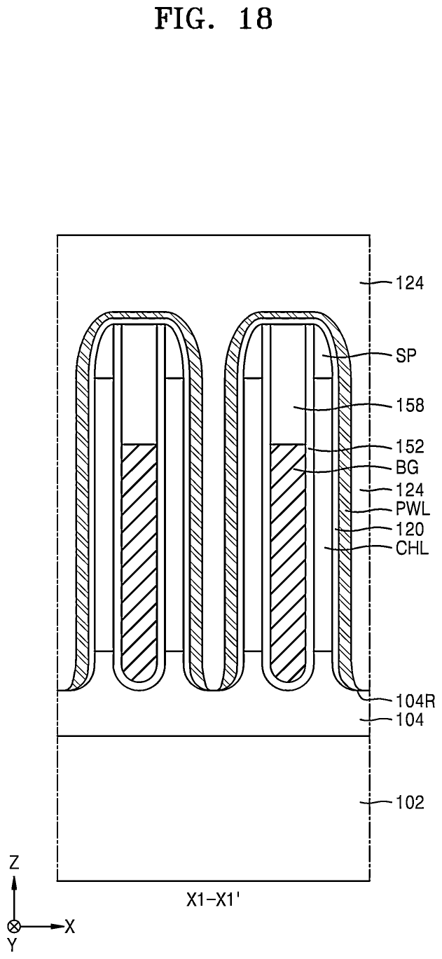

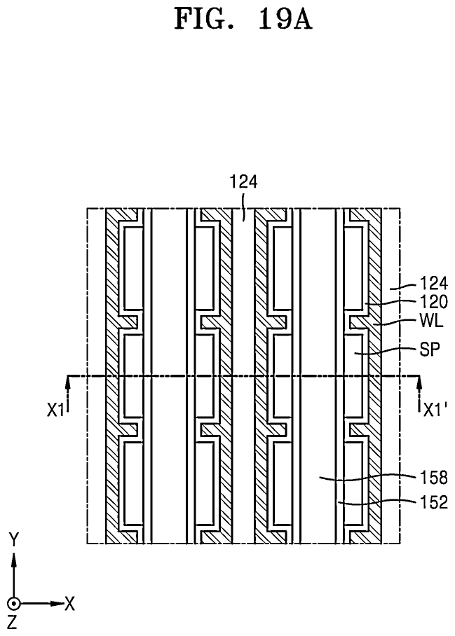

Referring to FIG. 18, a gate dielectric film 120 may be formed to conformally at least partially cover the resulting product of FIGS. 17A and 17B, followed by forming a conductive layer to conformally at least partially cover the gate dielectric film 120, and then, a portion of the conductive layer in each recess region 104R of the gap-fill insulating layer 104 may be etched, thereby dividing the conductive layer into a plurality of preliminary word lines PWL. Next, an isolation insulating pattern 124 may be formed to at least partially fill a space above each of the plurality of preliminary word lines PWL. The isolation insulating pattern 124 may be formed to at least partially fill each space between the plurality of preliminary word lines PWL and to at least partially cover the upper surface of each of the plurality of preliminary word lines PWL. A constituent material of the conductive layer may be the same as the constituent material of the word line WL described above.

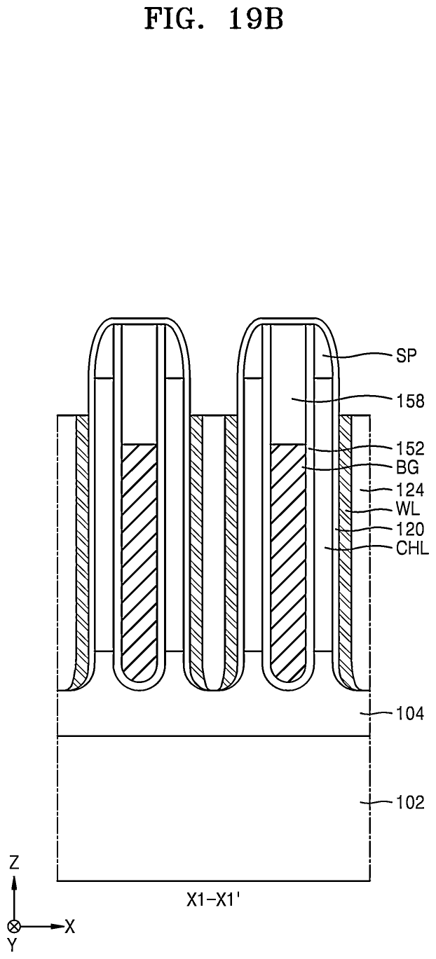

Referring to FIGS. 19A and 19B, in the resulting product of FIG. 18, each of the plurality of preliminary word lines PWL may be partially exposed by etching-back the isolation insulating pattern 124 such that an upper portion of the isolation insulating pattern 124 is removed, and each of the plurality of preliminary word lines PWL that are exposed may be etched, thereby forming a plurality of word lines WL.

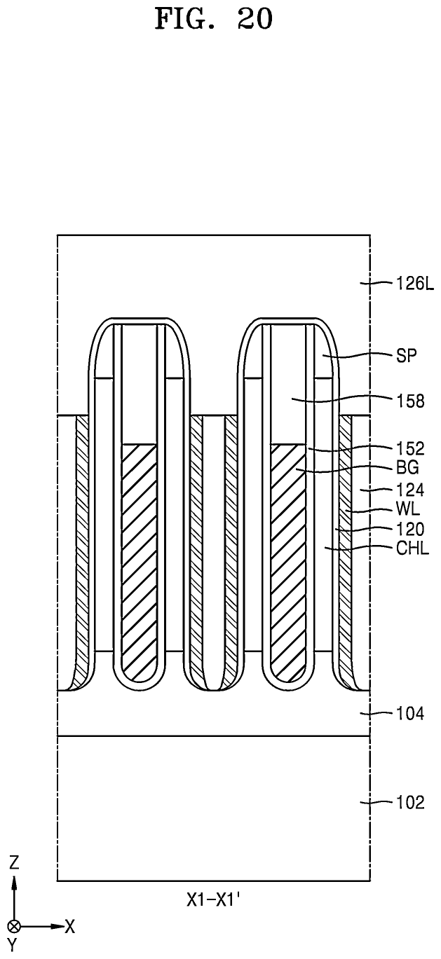

Referring to FIG. 20, a first gap-fill insulating film 126L may be formed to at least partially cover the resulting product of FIGS. 19A and 19B. A constituent material of the first gap-fill insulating film 126L may be the same as the constituent material of the first gap-fill insulating pattern 126 described above.

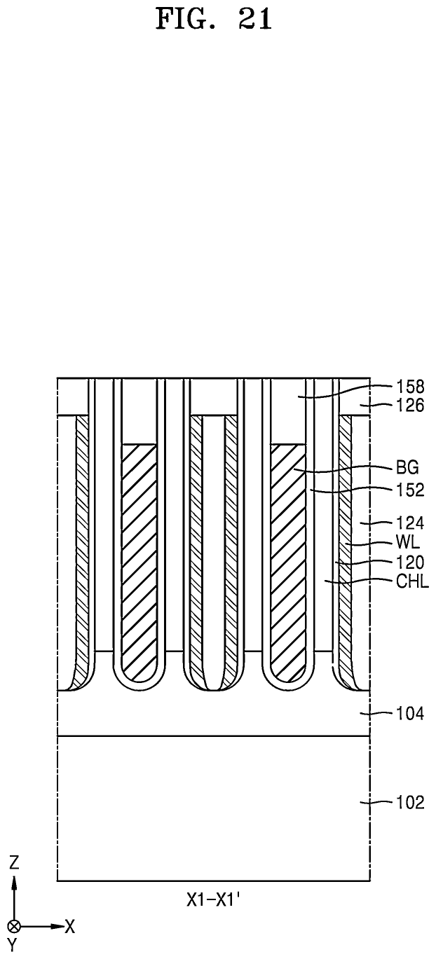

Referring to FIG. 21, a planarization process may be performed on the resulting product of FIG. 20 from the exposed upper surface of the first gap-fill insulating film 126L, thereby exposing the plurality of channel regions CHL and forming the first gap-fill insulating pattern 126 from the first gap-fill insulating film 126L. After the plurality of channel regions CHL are exposed, the height of the uppermost portion of each of the first capping insulating pattern 158 and the gate dielectric film 120 in the resulting product of FIG. 20 may be reduced.

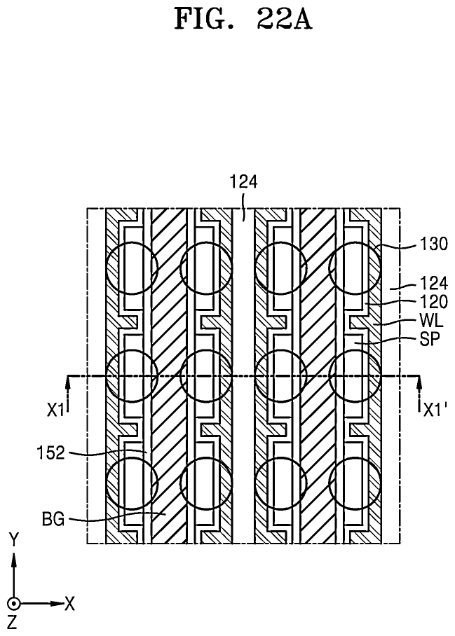

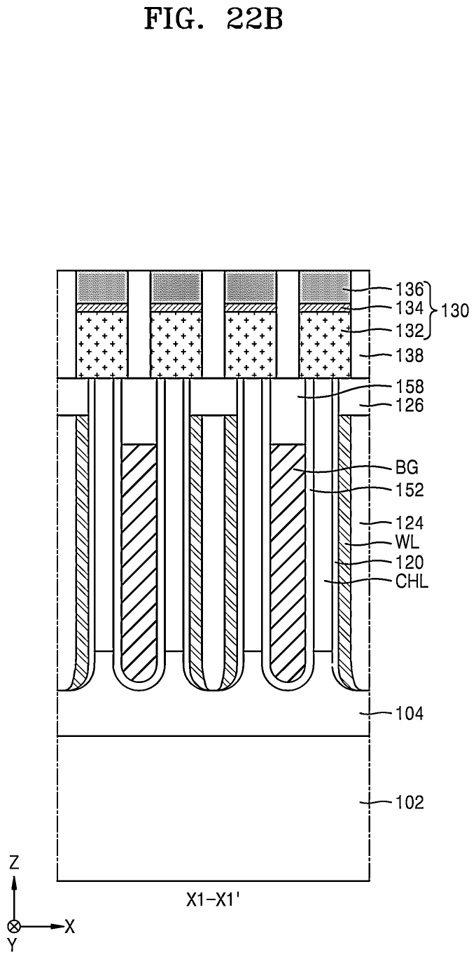

Referring to FIGS. 22A and 22B, in the resulting product of FIG. 21, a plurality of contact plugs 130 may be respectively formed on the plurality of channel regions CHL, and an interlayer dielectric 138 may be formed to at least partially fill each space between the plurality of contact plugs 130.

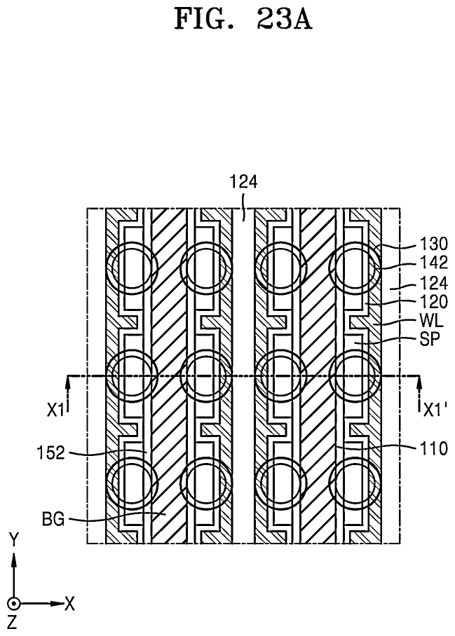

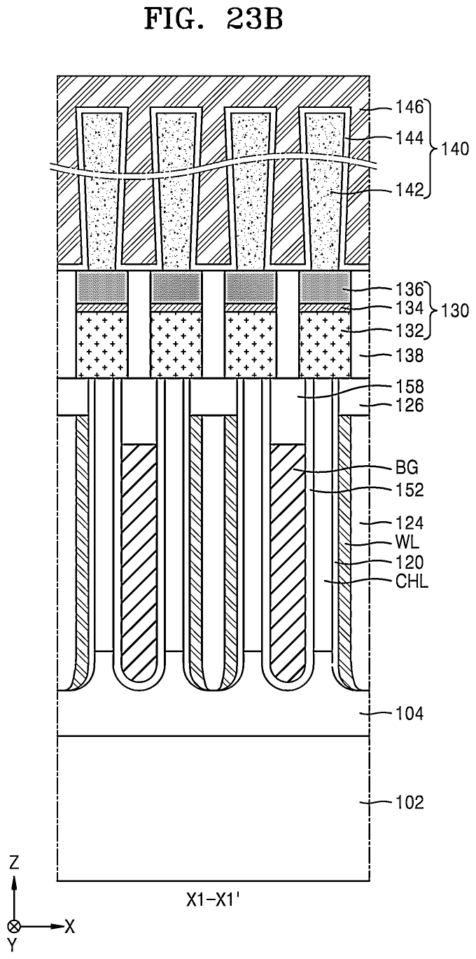

Referring to FIGS. 23A and 23B, a capacitor structure 140 may be formed on the resulting product of FIGS. 22A and 22B and may be connected to the plurality of contact plugs 130.

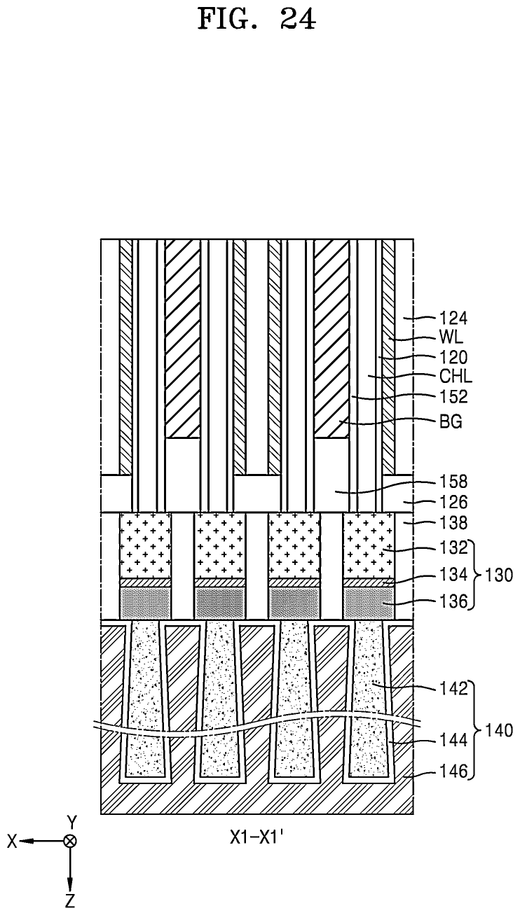

Referring to FIG. 24, the substrate 102 may face upwards in the vertical direction (Z direction) by turning the resulting product of FIGS. 23A and 23B upside-down, such that the directions, in which upper and lower portions of the resulting product of FIGS. 23A and 23B in terms of the vertical direction (Z direction) respectively face, are changed opposite to each other, and a grinding process and a wet etching process may be sequentially performed in the stated order on the substrate 102 from the backside surface of the substrate 102, which is exposed, such that the gap-fill insulating layer 104 and a sacrificial film 108 are at least partially exposed.

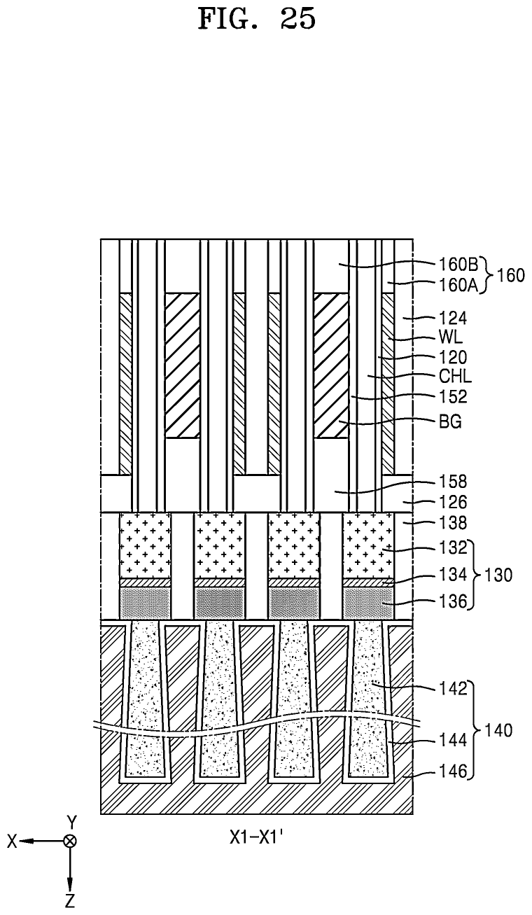

Referring to FIG. 25, in the resulting product of FIG. 24, a plurality of spaces may be prepared by removing a portion of each of the plurality of back gate electrodes BG and the plurality of word lines WL, which are at least partially exposed, and a plurality of second gap-fill insulating patterns 160A and a plurality of second capping insulating patterns 160B may be formed to at least partially fill the plurality of spaces. The plurality of second gap-fill insulating patterns 160A and the plurality of second capping insulating patterns 160B may constitute the gap-fill structure 160.

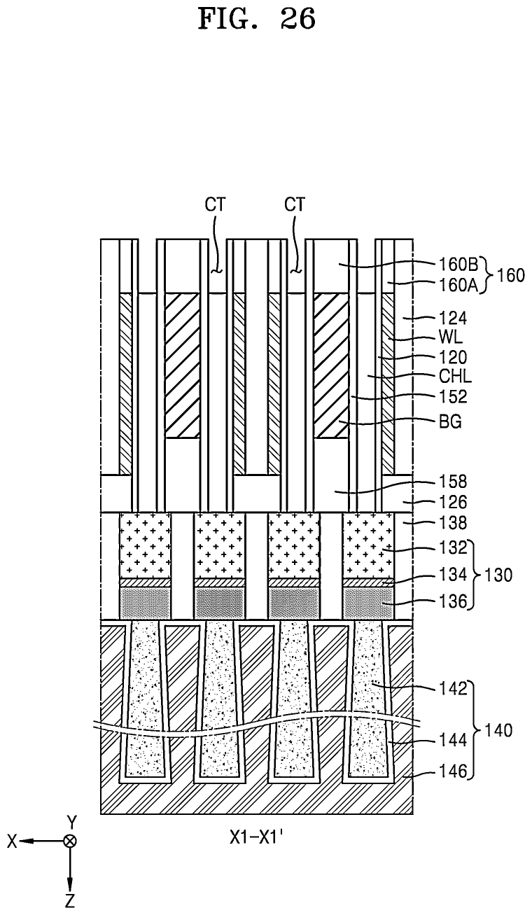

Referring to FIG. 26, in the resulting product of FIG. 25, a portion of each of the plurality of channel regions CHL, which are exposed, may be removed by an etch-back process, thereby preparing a plurality of contact spaces CT.

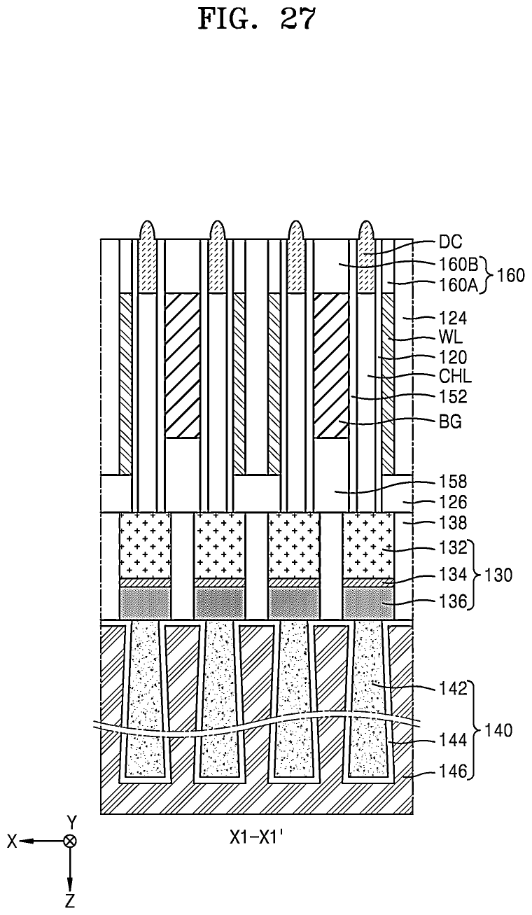

Referring to FIG. 27, in the resulting product of FIG. 26, an epitaxial growth process may be performed on the plurality of channel regions CHL exposed by the plurality of contact spaces CT, thereby forming a plurality of epitaxial direct contact plugs DC. During the formation of the plurality of epitaxial direct contact plugs DC, an impurity doping process may be performed by an in-situ doping process, thereby forming the plurality of epitaxial direct contact plugs DC each including a doped semiconductor film. By controlling various process conditions while the epitaxial growth process is performed, the epitaxial direct contact plug DC having the shape shown in FIGS. 2 and 3, the epitaxial direct contact plug DC4 having the shape shown in FIG. 6, the epitaxial direct contact plug DC5 having the shape shown in FIG. 7, the epitaxial direct contact plug DC6 having the shape shown in FIG. 8, the epitaxial direct contact plug DC7 having the shape shown in FIG. 9, or epitaxial direct contact plugs having various shapes modified and changed therefrom without departing from the scope of the inventive concept may be formed.

The epitaxial growth process for forming the plurality of epitaxial direct contact plugs DC may be performed at a relatively low process temperature selected from room temperature to about 480° C. Therefore, other components may not be damaged by heat during the formation of the plurality of epitaxial direct contact plugs DC.

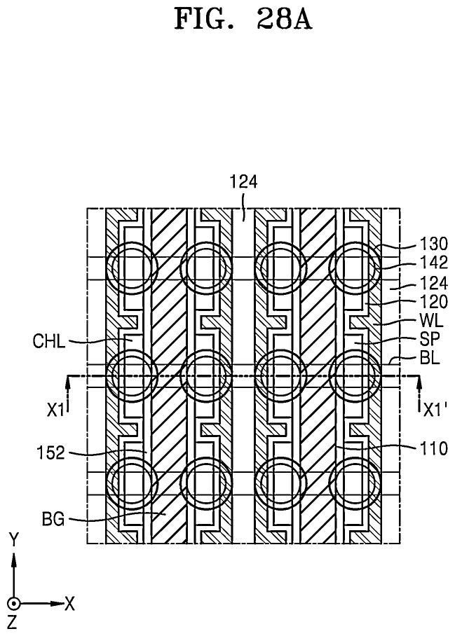

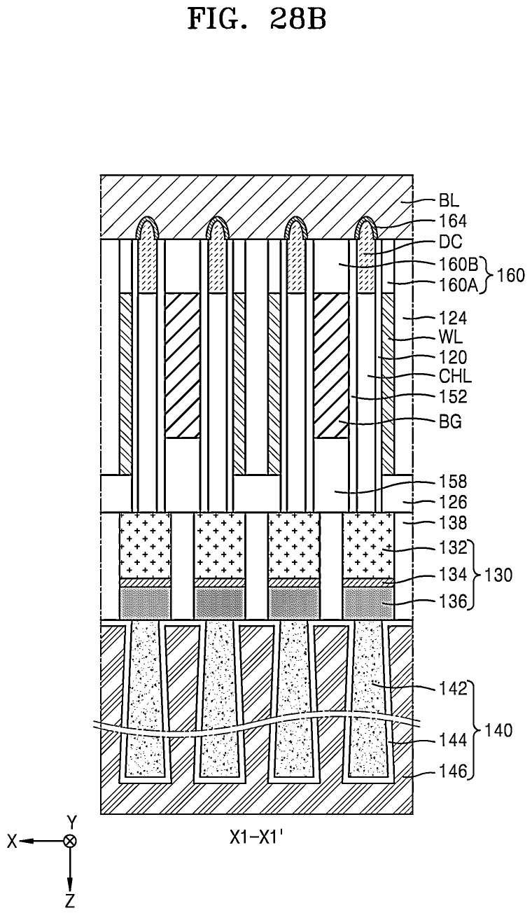

Referring to FIGS. 28A and 28B, in the resulting product of FIG. 27, a metal silicide film 164 and a conductive line BL may be formed to at least partially cover the surface of each of the plurality of epitaxial direct contact plugs DC that are exposed, thereby fabricating the semiconductor memory device 100 shown in FIGS. 1 to 3.

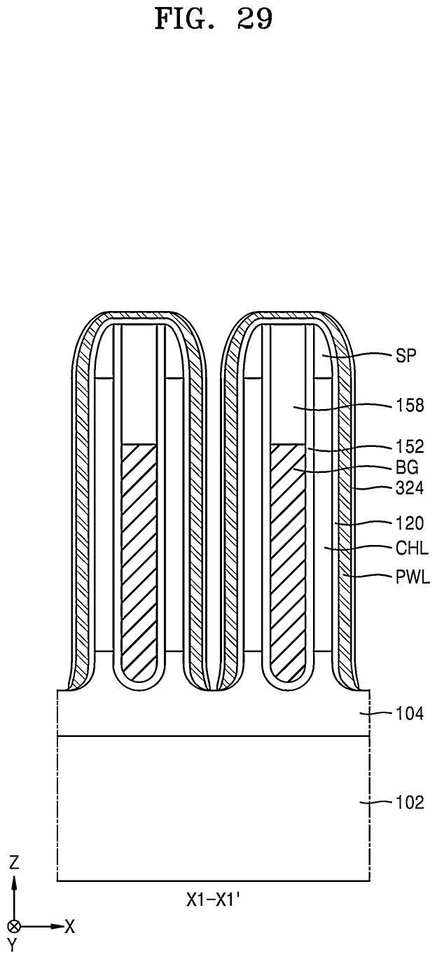

FIG. 29 is a cross-sectional view illustrating a method of fabricating a semiconductor memory device, according to some embodiments. FIG. 29 illustrates a cross-sectional configuration of a portion of the semiconductor memory device, which corresponds to the cross-section taken along the line X1-X1′ of FIG. 1, according to a fabrication process. An example of a method of fabricating the semiconductor memory device 300 shown in FIG. 5 is described with reference to FIG. 29. In FIG. 29, the same reference numerals as in FIGS. 1 to 28B respectively denote the same members, and here, repeated descriptions thereof are omitted.

Referring to FIG. 29, the processes described with reference to FIGS. 11A to 18 may be performed. However, after a conductive layer is formed to conformally at least partially cover the gate dielectric film 120 according to the process described with reference to FIG. 18, and before a portion of the conductive layer in the recess region 104R of the gap-fill insulating layer 104 is etched, the spacer insulating pattern 324 may be formed to at least partially cover a sidewall of the conductive layer, as shown in FIG. 29, and the conductive layer may be etched by using the spacer insulating pattern 324 as an etch mask, thereby dividing the conductive layer into the plurality of preliminary word lines PWL.

Next, while the spacer insulating pattern 324 is left on the sidewall of each of the plurality of preliminary word lines PWL, the processes described with reference to FIGS. 19A to 28B may be performed, thereby fabricating the semiconductor memory device 300 shown in FIG. 5.

Heretofore, although the examples of the methods of fabricating the semiconductor memory devices 100 and 300 shown in FIGS. 1 to 3 and FIG. 5 have been described with reference to FIGS. 11A to 29, it will be understood by those of ordinary skill in the art that semiconductor memory devices having various structures modified and changed from the semiconductor memory devices 100 and 300 shown in FIGS. 1 to 3 and FIG. 5 may be fabricated by making various modifications and changes to the examples described with reference to FIGS. 11A to 29 without departing from the spirit and scope of the inventive concept.

While embodiments of the inventive concept has been particularly shown and described with reference to embodiments thereof, it will be understood that various changes in form and details may be made therein without departing from the spirit and scope of the following claims.

What is claimed is:

1. A semiconductor memory device comprising:
a conductive line extending lengthwise in a first direction;
a plurality of channel regions arranged over the conductive line and spaced apart from each other in the first direction, each of the plurality of channel regions being configured to be electrically connected to the conductive line;
a back gate electrode spaced apart from the conductive line in a third direction and extending in a second direction between a first channel region and a second channel region, which are selected from the plurality of channel regions and are adjacent to each other, the first, second, and third directions being perpendicular with respect to each other;
a pair of word lines spaced apart from each other in the first direction and arranged between the second channel region and a third channel region, which are selected from the plurality of channel regions and are adjacent to each other; and
a plurality of epitaxial direct contact plugs extending in the third direction between the plurality of channel regions and the conductive line, each of the plurality of epitaxial direct contact plugs comprising a contact surface contacting one of the plurality of channel regions, a protruding contact portion at least partially surrounded by the conductive line, and a vertical contact portion extending in the third direction between the contact surface and the protruding contact portion.

2. The semiconductor memory device of claim 1, wherein each of the plurality of epitaxial direct contact plugs comprises a semiconductor film doped with a dopant.

3. The semiconductor memory device of claim 1, wherein a level of one end, which is closest to the conductive line, of each of the plurality of channel regions is apart from, in the third direction, a level of a surface of the conductive line, which is closest to the back gate electrode.

4. The semiconductor memory device of claim 1, wherein each of the back gate electrode and the pair of word lines has an end surface facing the conductive line and that is closest to the conductive line, and
a level of the end surface of each of the back gate and the pair of word lines is spaced apart from, in the third direction, a level of a surface of the conductive line, which is closest to the back gate electrode.

5. The semiconductor memory device of claim 1, further comprising:
a back gate dielectric film between the second channel region and the back gate electrode; and
a gate dielectric film between the second channel region and a first word line, which is closer to the second channel region, out of the pair of word lines,
wherein each of the back gate dielectric film and the gate dielectric film is in contact with the conductive line, and
wherein a width of the vertical contact portion of each of the plurality of epitaxial direct contact plugs in the first direction is defined by the back gate dielectric film and the gate dielectric film.

6. The semiconductor memory device of claim 1, further comprising:
a back gate dielectric film between the second channel region and the back gate electrode; and
a gate dielectric film between the second channel region and a first word line, which is closer to the second channel region, out of the pair of word lines,
wherein a first sidewall of the vertical contact portion of each of the plurality of epitaxial direct contact plugs in the first direction is in contact with the back gate dielectric film, and a second sidewall of the vertical contact portion of each of the plurality of epitaxial direct contact plugs in the first direction is in contact with the gate dielectric film.

7. The semiconductor memory device of claim 1, further comprising a plurality of metal silicide films respectively arranged between the plurality of epitaxial direct contact plugs and the conductive line.

8. The semiconductor memory device of claim 1, wherein each of the plurality of epitaxial direct contact plugs comprises a semiconductor film, and
wherein the protruding contact portion of each of the plurality of epitaxial direct contact plugs has a facet surface grown in a crystal direction of the semiconductor film.

9. The semiconductor memory device of claim 1, wherein each of the plurality of epitaxial direct contact plugs comprises a semiconductor film, and
wherein the protruding contact portion of each of the plurality of epitaxial direct contact plugs comprises an inclined surface that is inclined with respect to each of the first direction and the third direction.

10. The semiconductor memory device of claim 1, wherein, in each of the plurality of epitaxial direct contact plugs, a width of at least a portion of the protruding contact portion in the first direction is less than a width of the vertical contact portion in the first direction.

11. The semiconductor memory device of claim 1, wherein, in each of the plurality of epitaxial direct contact plugs, a width of at least a portion of the protruding contact portion in the first direction is greater than a width of the vertical contact portion in the first direction.

12. The semiconductor memory device of claim 1, further comprising a plurality of contact plugs, which are spaced apart from the conductive line in the third direction with the plurality of channel regions therebetween, each of the plurality of contact plugs being in contact with one channel region selected from the plurality of channel regions,
wherein the back gate electrode has a first end surface, which faces the plurality of contact plugs, and a second end surface, which faces the conductive line, and
wherein a distance in the third direction between a surface of the back gate electrode, which is closest to the plurality of contact plugs, and the plurality of contact plugs is greater than a distance in the third direction between a surface, which is closest to the plurality of contact plugs, in the pair of word lines and the plurality of contact plugs.

13. A semiconductor memory device comprising:
a conductive line extending lengthwise in a first direction;
a plurality of channel regions arranged apart from each other in the first direction and spaced apart from the conductive line in a third direction;
a plurality of contact plugs spaced apart from the conductive line in the third direction with the plurality of channel regions therebetween;
a back gate electrode spaced apart from the conductive line in the third direction and extending lengthwise in a second direction between a first channel region and a second channel region, which are selected from the plurality of channel regions and are adjacent to each other, the first, second, and third directions being perpendicular with respect to each other;
a back gate dielectric film arranged between the back gate electrode and the second channel region and contacting each of the back gate electrode and the second channel region;
a word line spaced apart from the back gate electrode in the first direction with the second channel region therebetween;
a gate dielectric film arranged between the word line and the second channel region and contacting each of the word line and the second channel region; and
an epitaxial direct contact plug extending in the third direction between the first channel region and the conductive line, the epitaxial direct contact plug comprising a contact surface contacting the second channel region, a protruding contact portion at least partially surrounded by the conductive line, and a sidewall extending in the third direction between the contact surface and the protruding contact portion and contacting each of the back gate dielectric film and the gate dielectric film.

14. The semiconductor memory device of claim 13, wherein the epitaxial direct contact plug comprises a silicon film doped with a dopant.

15. The semiconductor memory device of claim 13, wherein each of the back gate electrode and the word line has an end surface facing the conductive line and closest to the conductive line, and
wherein a level of the end surface of each of the back gate electrode and the word line is spaced apart from, in the third direction, a level of a surface of the conductive line, which is closest to the back gate electrode.

16. The semiconductor memory device of claim 13, wherein each of the back gate dielectric film and the gate dielectric film is in contact with the conductive line, and
wherein the epitaxial direct contact plug further protrudes more toward the conductive line than the back gate dielectric film and the gate dielectric film.

17. The semiconductor memory device of claim 13, further comprising a metal silicide film between the epitaxial direct contact plug and the conductive line.

18. The semiconductor memory device of claim 13, wherein the epitaxial direct contact plug comprises a doped silicon film, and
wherein the protruding contact portion of the epitaxial direct contact plug has a facet surface grown in a crystal direction of the doped silicon film.

19. The semiconductor memory device of claim 13, wherein the epitaxial direct contact plug comprises a doped silicon film, and
wherein the protruding contact portion of the epitaxial direct contact plug comprises an inclined surface that is inclined with respect to each of the first direction and the third direction.

20. A semiconductor memory device comprising:
a plurality of conductive lines, which extend lengthwise in a first direction and are spaced apart from each other in a second direction;
a plurality of contact plugs spaced apart from the plurality of conductive lines in a third direction, the first, second, and third directions being perpendicular with respect to each other;
a plurality of channel regions arranged between the plurality of conductive lines and the plurality of contact plugs, the plurality of channel regions each having one end spaced apart from the plurality of conductive lines in the third direction and the other end connected to one contact plug selected from the plurality of contact plugs;
a plurality of back gate electrodes, which are spaced apart from each other in the first direction and extend lengthwise in the second direction between the plurality of conductive lines and the plurality of contact plugs;
a plurality of back gate dielectric films respectively contacting the plurality of back gate electrodes;
a plurality of word lines extending lengthwise in the second direction between the plurality of conductive lines and the plurality of contact plugs;
a plurality of gate dielectric films respectively contacting the plurality of word lines; and
a plurality of epitaxial direct contact plugs extending in the third direction between the plurality of channel regions and the plurality of conductive lines, each of the plurality of epitaxial direct contact plugs comprising a contact surface contacting one channel region selected from the plurality of channel regions, a protruding contact portion at least partially surrounded by one conductive line selected from the plurality of conductive lines, and a sidewall that extends in the third direction between the contact surface and the protruding contact portion and is in contact with each of one back gate dielectric film selected from the plurality of back gate dielectric films and one gate dielectric film selected from the plurality of gate dielectric films.
